(19) United States
(12) Patent Application Publication
(10) Pub. No.: US 2026/0255810 A1
(43) Pub. Date: Aug. 27, 2026

(54) Display Device And Electronic Device Including The Same

(71) Applicant: Samsung Display Co., Ltd., Yongin-si (KR)

(72) Inventor: Kwang Jin Jeong, Yongin-si (KR)

(73) Assignee: Samsung Display Co., Ltd., Yongin-si (KR)

(21) Appl. No.: 19/345,016

(22) Filed: Sep. 30, 2025

(30) Foreign Application Priority Data
Feb. 26, 2025 (KR) 10-2025-0024726

(51) Int. Cl. H10K 59/124; H10K 59/131

(52) U.S. Cl. CPC H10K 59/124; H10K 59/131

(57) ABSTRACT

A display device includes a substrate including a display area and a non-display area outside the display area, a pixel disposed in the display area, an insulating pattern disposed in the non-display area, and a signal line disposed on the substrate. The signal line includes a first portion that overlaps the insulating pattern and a second portion that does not overlap the insulating pattern. The first portion protrudes further from an upper surface of the substrate than the second portion, and the first portion of the signal line is an alignment mark.

### CROSS-REFERENCE TO RELATED APPLICATIONS

This application claims priority to and the benefit of Korean Patent Application No. 10-2025-0024726, filed on February 26, 2025 in the Korean Intellectual Property Office, the disclosure of which is incorporated by reference herein in its entirety.

### TECHNICAL FIELD

The present disclosure relates to a display device and an electronic device including the display device.

### BACKGROUND

In general, electronic devices include two or more electronic components. For example, electronic devices such as mobile phones, laptop computers, and televisions include a display panel generating images, a main wiring board, and a flexible wiring board.

A process that electrically connects pad portions of two electronic components (i.e., a bonding process) includes operations of aligning and combining the pad portions of the two electronic components. An alignment mark is formed near the pad portions of the electronic components to enhance alignment accuracy. The alignment mark serves as a reference point during the alignment operation performed with an optical device and enables a highly precise bonding process.

### SUMMARY

The present disclosure provides a display device including an alignment mark with enhanced visibility.

The present disclosure provides an electronic device including the alignment mark with enhanced visibility.

Aspects of the present disclosure provide a display device including a substrate including a display area and a non-display area defined outside the display area, a pixel disposed in the display area, an insulating pattern disposed in the non-display area, and a signal line disposed on the substrate. The signal line includes a first portion that overlaps the insulating pattern and a second portion that does not overlap the insulating pattern. The first portion protrudes further from an upper surface of the substrate than the second portion, and the first portion of the signal line is an alignment mark.

A thickness of the insulating pattern at a second point, which is closer to a center of the insulating pattern than a first point of the insulating pattern, is greater than a thickness measured at the first point.

A luminance of the first portion is different from a luminance of the second portion when viewed from the upper surface of the substrate.

The insulating pattern has a width smaller than a width of the signal line.

The signal line is provided in plural, the signal lines include a first signal line and a second signal line spaced apart from the first signal in a first direction, the first portion of the first signal line is defined as a first alignment mark, the first portion of the second signal line is defined as a second alignment mark, and the first alignment mark and the second alignment mark are spaced apart from each other in the first direction.

An imaginary line passing through a center of the substrate in the first direction is defined, i.e. a center line, the first signal line is disposed at one side of the imaginary line in the first direction, the second signal line is disposed at the other side of the imaginary line in the first direction, and the first alignment mark and the second alignment mark are symmetrical with each other with respect to the imaginary line.

The display device further includes at least one insulating layer disposed on the signal line. The area of the at least one insulating layer overlapping the insulating pattern further protrudes from the upper surface of the substrate than the area of the at least one insulating layer non-overlapping the insulating pattern..

The first portion of the signal line is visually recognized above the at least one insulating layer.

The display device further includes a pad disposed in the non-display area, and the signal line electrically connects the pad and the pixel.

The display device further includes a base insulating layer disposed on the pixel and an input sensor electrode disposed on the base insulating layer, and the signal line is electrically connected to the input sensor electrode.

The insulating pattern is disposed on the base insulating layer.

Aspects of the present disclosure provide a display device including a substrate including a display area and a non-display area defined outside the display area, a pixel disposed in the display area, a pad disposed in the non-display area, a signal line electrically connecting the pixel and the pad, and an alignment mark defined by the signal line protruding while overlapping the non-display area.

A luminance of the alignment mark is different from a luminance of a portion of the signal line except the alignment mark of the signal line when viewed from an upper surface of the substrate.

The signal line is provided in plural, the signal lines include a first signal line and a second signal line spaced apart from the first signal in a first direction, the first signal line includes a first alignment mark, the second signal line includes a second alignment mark, , and the first alignment mark and the second alignment mark are symmetrical with each other with respect to a center line.

Aspects of the present disclosure provide an electronic device including a display device and at least one processor controlling the display device. The display device includes a substrate including a display area and a non-display area defined outside the display area, a pixel disposed in the display area, a pad disposed in the non-display area and electrically connected to the pixel, a first insulating pattern disposed in the non-display area, and a signal line including a portion overlapping the first insulating pattern and electrically connected to the pad. A first portion of the signal line, which overlaps the first insulating pattern, further protrudes from an upper surface of the substrate than a second portion of the signal line, which does not overlap the first insulating pattern, and a width of the first portion decreases as a distance from an upper surface of the first portion decreases when viewed in a plane.

The first insulating pattern is fully covered by the signal line.

The signal line is provided in plural, the signal lines include a first signal line and a second signal line spaced apart from the first signal in a first direction, the first portion of the first signal line is a first alignment mark, the first portion of the second signal line is a second alignment mark, and the first alignment mark and the second alignment mark are spaced apart from each other in the first direction.

The first alignment mark and the second alignment mark are spaced apart from an edge of the display device by a same distance in a second direction perpendicular to the first direction.

The electronic device further includes a circuit element layer disposed on the substrate and including a transistor, a display element layer disposed on the circuit element layer and including a display element, a thin film encapsulation layer disposed on the display element layer, and an input sensor layer including an input sensor electrode disposed on the thin film encapsulation layer.

The electronic device further includes a second insulating pattern disposed on the thin film encapsulation layer and an input signal line electrically connecting the pad and the input sensor electrode. A portion of the input signal line, which overlaps the second insulating pattern, overlaps the non-display area and protrudes from the input signal line.

According to the above, the alignment mark is formed in the signal line. This is because that a protruding metal is clearly visible even when formed at a very small size. Accordingly, the alignment mark is able to be placed in a narrow bezel area without a conventional space constraint required not to keep the alignment mark from overlapping the signal line.

### BRIEF DESCRIPTION OF THE DRAWINGS

FIG. 1 is a block diagram of an electronic device according to an aspect of the present disclosure;

FIG. 2 is a schematic view of electronic devices according to aspects of the present disclosure;

FIGS. 3A and 3B are perspective views of a display device according to an aspect of the present disclosure;

FIG. 4 is a cross-sectional view of a display device according to an aspect of the present disclosure;

FIG. 5 is a plan view of a display panel according to an aspect of the present disclosure;

FIG. 6 is a plan view of an input sensor layer according to an aspect of the present disclosure;

FIG. 7 is a plan view of a signal line of an input sensor layer according to an aspect of the present disclosure;

FIG. 8 is a plan view of a signal line of an input sensor layer according to an aspect of the present disclosure;

FIG. 9 is a cross-sectional view of a display device taken along a line I-I’ of FIG. 6;

FIG. 10 is an enlarged plan view of a portion AA’ of FIG. 7; and

FIG. 11 is a schematic view of the imaging of an alignment mark.

### DETAILED DESCRIPTION

In the present disclosure, it will be understood that when an element (or area, layer, or portion) is referred to as being "on", "connected to" or "coupled to" another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, aspects of the present disclosure will be described with reference to accompanying drawings.

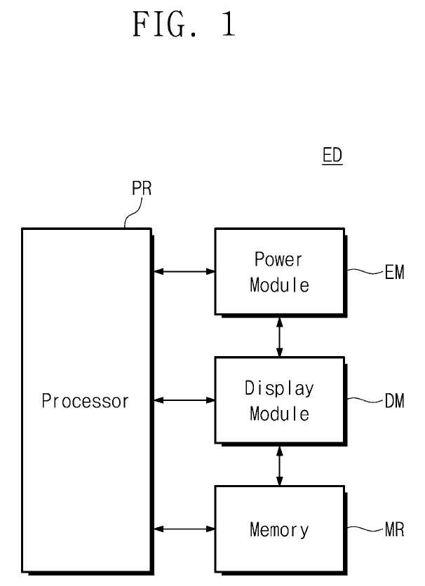

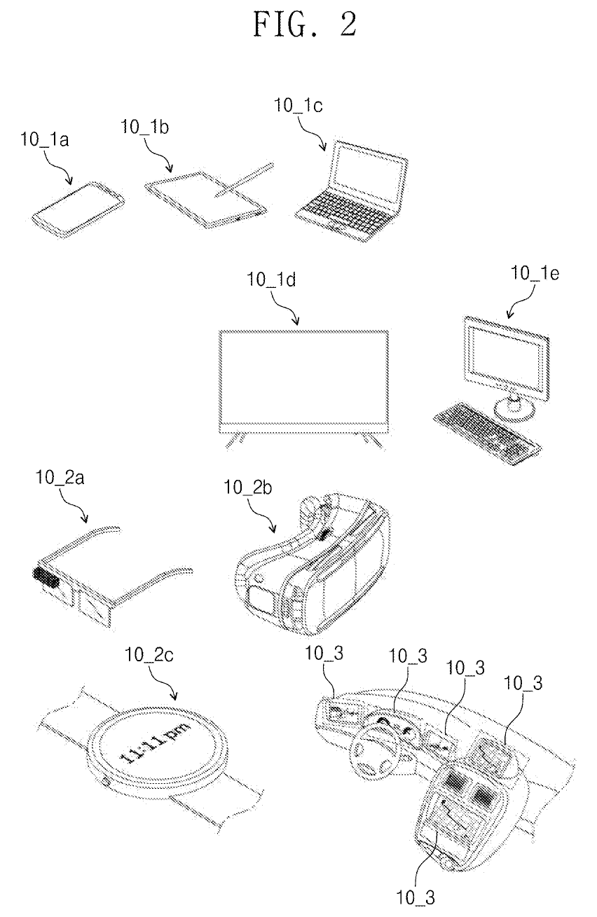

FIG. 1 is a block diagram of an electronic device according to an aspect of the present disclosure. FIG. 2 is a schematic view of electronic devices according to aspects of the present disclosure.

The display device according to the present disclosure may be applied to various electronic devices. The electronic device according to the present disclosure includes the display device and may further include modules or devices having additional functions in addition to the display device.

FIG. 1 is a block diagram of the electronic device according to the aspect of the present disclosure. Referring to FIG. 1, the electronic device ED may include a display module DM, a processor PR, a memory MR, and a power module EM.

The processor PR may include at least one of a central processing unit (CPU), an application processor (AP), a graphics processing unit (GPU), a communication processor (CP), an image signal processor (ISP), and a controller.

The memory MR may store data information required for the operation of the processor PR or the display module DM. When the processor PR executes an application stored in the memory MR, an image data signal and/or an input control signal may be transmitted to the display module DM, and the display module DM may process the received signals to output image information through a display screen.

The power module EM may include a power supply module, such as a power adapter or a battery device, and a power conversion module that converts power supplied by the power supply module to generate power required for the operation of the electronic device ED.

At least one of components of the electronic device ED may be included in the display device according to aspects described below. In addition, among individual modules that are functionally included within a single module, some may be included in the display device while others may be provided separately from the display device. As an example, the display device may include the display module DM, and the processor PR, the memory MR, and the power module EM may be provided as separate devices within the electronic device ED without being included in the display device.

FIG. 2 is a schematic view of various electronic devices according to aspects of the present disclosure.

Referring to FIG. 2, various electronic devices to which the display device according to aspects is applied may include an electronic device to display images, such as a smartphone 10_1a, a tablet PC 10_1b, a laptop computer 10_1c, a television 10_1d, a desktop monitor 10_1e, etc., a wearable electronic device including a display module, such as a smart glasses 10_2a, a head-mounted display 10_2b, a smartwatch 10_2c, etc., or an in-vehicle electronic device 10_3 including a display module, such as an instrument panel, a center fascia, a dashboard-mounted center information display (CID), or a room mirror display.

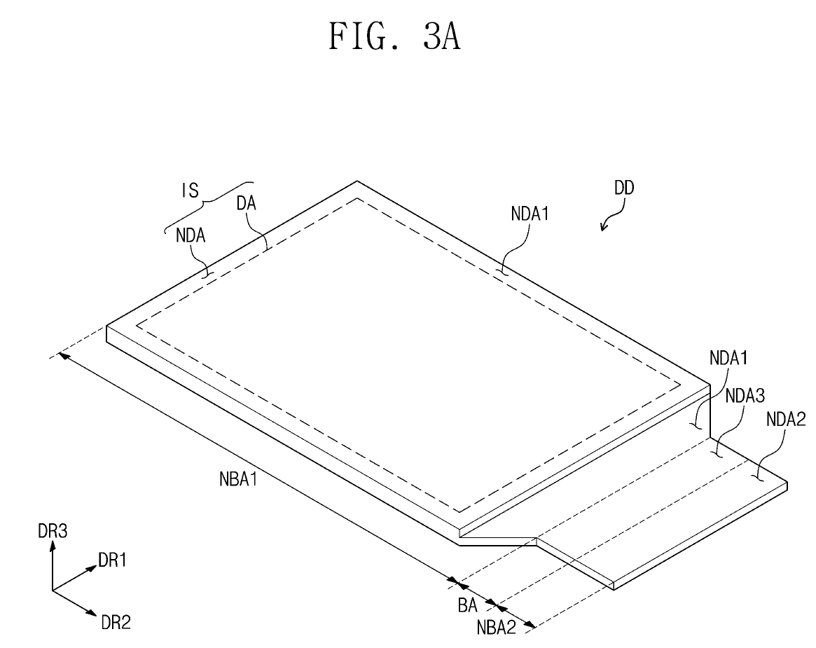

FIGS. 3A and 3B are perspective views of the display device DD according to an aspect of the present disclosure.

Referring to FIGS. 3A and 3B, a display surface IS through which an image is displayed may be substantially parallel to a plane defined by a first directional axis DR1 and a second directional axis DR2. A third directional axis DR3 may indicate a normal line direction of the display surface IS, i.e., a thickness direction of the display device DD. Front (or upper) and rear (or lower) surfaces of each member may be distinguished from each other with respect to the third directional axis DR3. However, directions indicated by the first, second, and third directional axes DR1, DR2, and DR3 may be relative to each other and may be changed to other directions. Hereinafter, first, second, and third directions may correspond to directions respectively indicated by the first, second, and third directional axes DR1, DR2, and DR3 and may be assigned with the same reference numerals as the first, second, and third directional axes DR1, DR2, and DR3.

The display device DD according to the present aspect may be a flexible display device, however, it should not be limited thereto or thereby. According to an aspect, a display device DD may be a rigid display device DD. The display device DD according to the present aspect may be applied to a large-sized electronic device, such as a television set, a monitor, etc., and a small and medium-sized electronic device, such as a mobile phone, a tablet computer, a car navigation unit, a game unit, a smart watch, etc.

Referring to FIGS. 3A and 3B, the display device DD may include a display area DA through which the image is displayed and a non-display area NDA adjacent to the display area DA. The image may not be displayed through the non-display area NDA. As an example, the display area DA may have a quadrangular shape. The non-display area NDA may surround the display area DA. However, the present disclosure should not be limited thereto or thereby, and the shape of the display area DA and the shape of the non-display area NDA may be changed. For instance, the non-display area NDA may be disposed to be adjacent to only a portion of the display area DA.

According to an aspect, a portion of the display device DD may be bent. The display device DD may include a first non-bending area NBA1, a second non-bending area NBA2 spaced apart from the first non-bending area NBA1 in the second direction DR2, and a bending area BA defined between the first non-bending area NBA1 and the second non-bending area NBA2. The non-display area NDA may include a portion of the first non-bending area NBA1, the bending area BA, and the second non-bending area NBA2.

The bending area BA may be bent with respect to a bending axis BX defined in the first direction DR1. In the bent state, the second non-bending area NBA2 may face the first non-bending area NBA1. The bending area BA and the second non-bending area NBA2 may have a width smaller than that of the first non-bending area NBA1 in the first direction DR1.

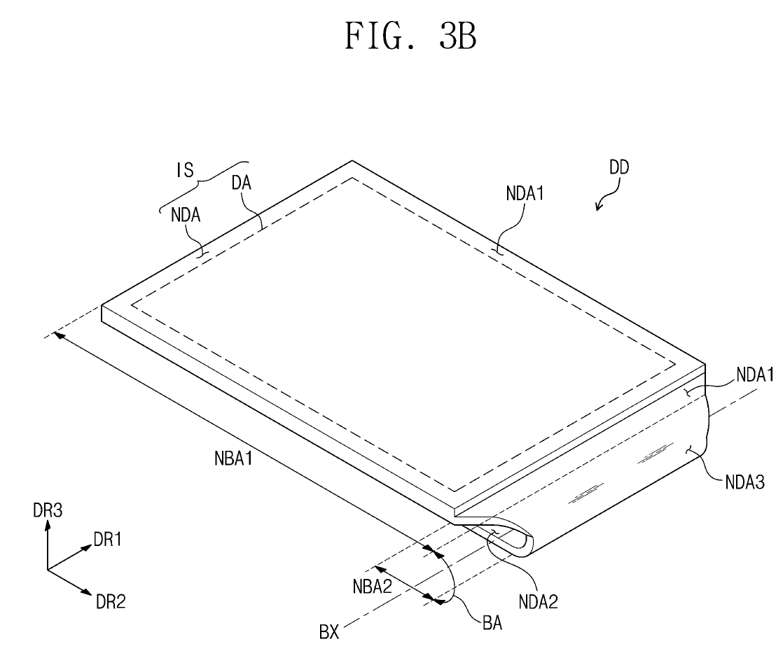

The above description of the display area DA, the non-display area NDA, the first non-bending area NBA1, the second non-bending area NBA2, and the bending area BA may be equally applied to a display panel DP (refer to FIG. 4) and an input sensor layer ISL (refer to FIG. 4) that are components of the display device DD.

FIG. 4 is a cross-sectional view of the display device according to an aspect of the present disclosure. FIG. 4 shows a cross-section defined by the second direction DR2 and the third direction DR2.

The display device DD may include the display panel DP and the input sensor layer ISL. Although not shown separately, the display device DD may further include a protective member disposed on a lower surface of the display panel DP and an anti-reflective member disposed on an upper surface of the input sensor layer ISL.

The display panel DP may be a light emitting type display panel, however, it is not be particularly limited. For instance, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot, a quantum rod, or a micro-LED. Hereinafter, the organic light emitting display panel will be described as the display panel DP.

The display panel DP may include a base layer BL and a circuit element layer DP-CL, a display element layer DP-OLED, and an upper insulating layer TFL, which are disposed on the base layer BL. The input sensor layer ISL may be disposed directly on the upper insulating layer TFL. In the present disclosure, the expression “component A is disposed directly on component B” means that there are no intervening adhesive layers between component A and component B.

The base layer BL may include at least one plastic film. The base layer BL (or a substrate) may include a plastic substrate, a glass substrate, a metal substrate, or an organic/inorganic composite material substrate. The display area DA and the non-display area NDA, which are described with reference to FIGS. 3A and 3B, may be equally applied to the base layer BL.

The circuit element layer DP-CL may include at least one insulating layer and a circuit element. The insulating layer may include at least one inorganic layer and at least one organic layer. The circuit element may include signal lines and a pixel driving circuit. This will be described in detail later.

The display element layer DP-OLED may include a display element. The display element layer DP-OLED may further include an organic layer such as a pixel definition layer.

The upper insulating layer TFL may include a plurality of thin layers. Some thin layers may be provided to improve optical efficiency, and some thin layers may be provided to protect organic light emitting diodes. The upper insulating layer TFL will be described in detail later.

The input sensor layer ISL may obtain coordinate information of an external input. The input sensor layer ISL may have a multi-layer structure. The input sensor layer ISL may include a conductive layer with a single layer structure or conductive layers with multi-layer structure. The input sensor layer ISL may include an insulating layer with a single layer structure or insulating layers with multi-layer structure. The input sensor layer ISL may sense the external input in a capacitive method. In the present disclosure, an operation method of the input sensor layer ISL should not be particularly limited. According to an aspect, the input sensor layer ISL may sense the external input using an electromagnetic induction method or a pressure sensing method.

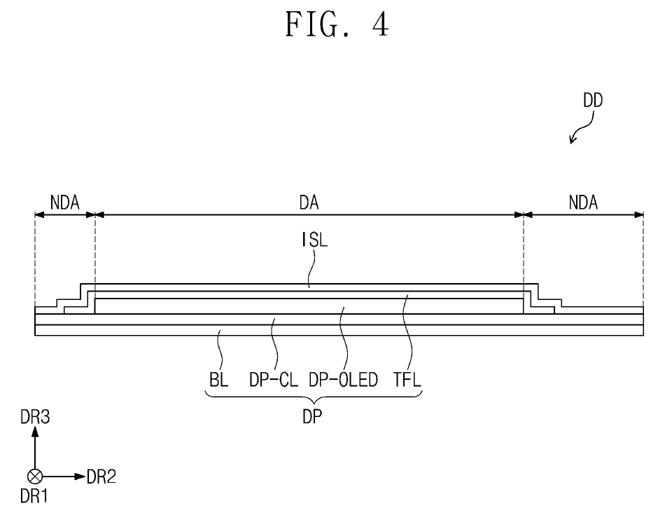

FIG. 5 is a plan view of the display panel according to an aspect of the present disclosure.

Referring to FIG. 5, the display panel DP may include a display area DP-DA and a non-display area DP-NDA when viewed in a plane. In an aspect, the non-display area DP-NDA may be defined along an edge of the display area DP-DA. The display area DP-DA and the non-display area DP-NDA of the display panel DP may respectively correspond to the display area DA and the non-display area NDA of the display device DD shown in FIGS. 3A and 3B.

The display panel DP may include a first non-bending area DP-N1, a second non-bending area DP-N2, and a bending area DP-B, which respectively correspond to the first non-bending area NBA1, the second non-bending area NBA2, and the bending area BA shown in FIGS. 3A and 3B. Areas of the display panel DP and areas of the display device DD that correspond to each other do not necessarily have to be the same as each other and may vary depending on the structure/design of the display panel DP.

The display panel DP may include a driving circuit GDC, a plurality of signal lines SGL, and a plurality of pixels PX. The pixels PX may be arranged in the display area DP-DA. Each of the pixels PX may include an organic light emitting diode and a pixel driving circuit connected to the organic light emitting diode. The driving circuit GDC, the signal lines SGL, and the pixel driving circuit may be included in the circuit element layer DP-CL shown in FIG. 4.

The driving circuit GDC may include a scan driving circuit. The scan driving circuit may generate a plurality of scan signals and may sequentially output the scan signals to a plurality of scan lines GL described later. The scan driving circuit may further output other control signal to the pixel driving circuit.

The scan driving circuit may include a plurality of thin film transistors formed through the same process as the driving circuit of the pixels PX, e.g., a low temperature polycrystalline silicon (LTPS) process or a low temperature polycrystalline oxide (LTPO) process.

The signal lines SGL may include the scan lines GL, data lines DL, a power line PL, and a control signal line CSL. Each of the scan lines GL may be connected to a corresponding pixel PX among the pixels PX, and each of the data lines DL may be connected to a corresponding pixel PX among the pixels PX. The power line PL may be connected to the pixels PX. The control signal line CSL may provide control signals to the scan driving circuit.

The display panel DP may include signal pads DP-PD connected to ends of the signal lines SGL. In the non-display area DP-NDA, an area in which the signal pads DP-PD are arranged may be defined as a pad area NDA-PD.

An alignment mark AM may be disposed in the non-display area DP-NDA. The alignment mark AM may be contained in a portion of the signal lines SGL. For illustration purposes, the alignment mark AM is depicted as having a greater width than the signal lines SGL, however, the alignment mark AM may have a width equal to or smaller than that of the signal lines SGL.

The alignment marks AM may be spaced apart from each other in the first direction DR1 in the substrate and may be symmetrically formed. The symmetrically-formed alignment marks AM may have the same shape and size as each other.

Since the portion of the signal line functions as the alignment mark AM, the alignment mark AM may perform alignment functions effectively even in a narrow space without interfering with the signal line or without reducing the resistance of the signal line. This may reduce spatial constraints associated with the alignment mark.

The display panel DP may further include an insulating line BNP. The insulating line BNP may be disposed in the non-display area DP-NDA. The insulating line BNP may act as a dam to prevent liquid organic substances from overflowing in an inkjet process of the display panel DP.

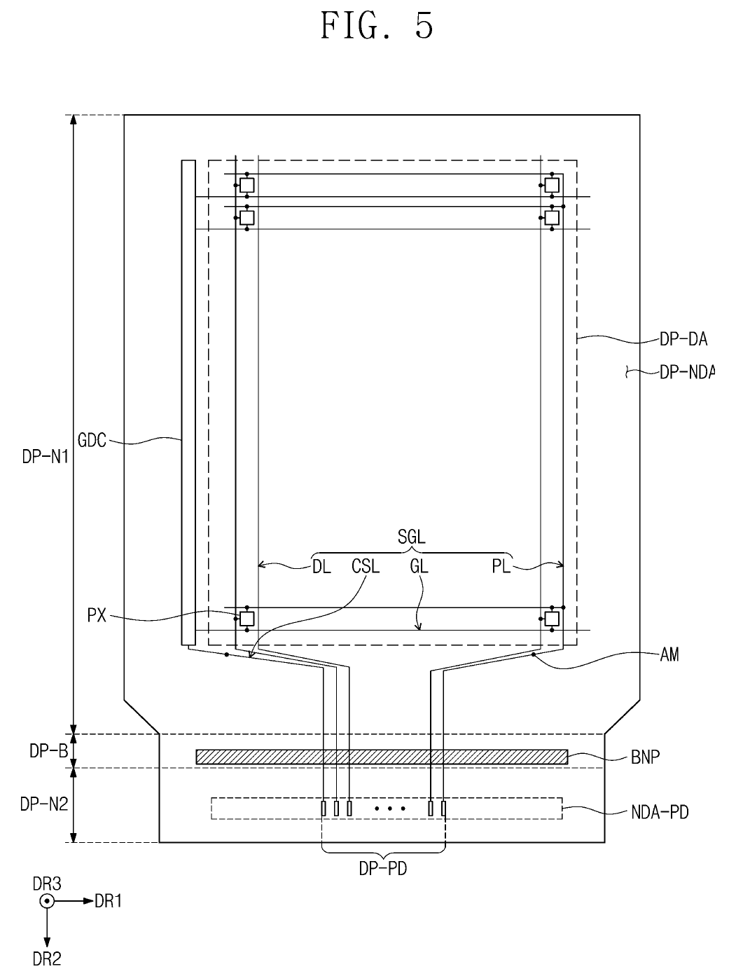

FIG. 6 is a plan view of the input sensor layer according to an aspect of the present disclosure.

Referring to FIG. 6, first electrodes E1-1 to E1-5 and second electrodes E2-1 to E2-4 insulated from the first electrodes E1-1 to E1-5 while intersecting the first electrodes E1-1 to E1-5 may be arranged in the display area DA. Any one of the first electrodes E1-1 to E1-5 and the second electrodes E2-1 to E2-4 may have an integral shape. FIG. 6 shows the first electrodes E1-1 to E1-5 having the integral shape as a representative example. The first electrodes E1-1 to E1-5 may include sensing portions SP1 and intermediate portions CP1.

First input signal lines SL1 electrically connected to the first electrodes E1-1 to E1-5 and second input signal lines SL2 electrically connected to the second electrodes E2-1 to E2-4 may be arranged in the non-display area NDA. Any one of the first input signal lines SL1 and the second input signal lines SL2 may apply a transmission signal from an external circuit to corresponding electrodes to sense an external input, and the other may transmit a variation in capacitance between the first electrodes E1-1 to E1-5 and the second electrodes E2-1 to E2-4 to the external circuit as a reception signal. However, the input signal lines SL1 and SL2 may be arranged not only in the non-display area NDA but also in the display area DA. The first electrodes E1-1 to E1-5 and the second electrodes E2-1 to E2-4 may be referred to as an input sensor electrode.

The non-display area NDA may include the pad area NDA-PD connected to the input signal lines SL1 and SL2. The input signal lines SL1 and SL2 may electrically connect a pad electrode ISL-PD in the pad area NDA-PD and the first electrodes E1-1 to E1-5 or the second electrodes E2-1 to E2-4.

The alignment mark AM may include first, second, third, and fourth alignment marks AM1, AM2, AM3, and AM4. An imaginary line CL passing through a center of the input sensor layer ISL may be defined, i.e. a center line, the first alignment mark AM1 and the third alignment mark AM3 may be arranged at one side with respect to the imaginary line CL in the first direction DR1, and the second alignment mark AM2 and the fourth alignment mark AM4 may be arranged at the other side with respect to the imaginary line CL in the first direction DR1. The first alignment mark AM1 and the second alignment mark AM2 may be symmetrically disposed with respect to the imaginary line CL in the first direction DR1, and the third alignment mark AM3 and the fourth alignment mark AM4 may be symmetrically disposed with respect to the imaginary line CL in the first direction DR1.

Although not shown separately, an imaginary extension line extending from the first alignment mark AM1 toward the second alignment mark AM2 may be parallel to an edge of a lower surface of the input sensor layer ISL in the second direction DR2. An imaginary extension line extending from the third alignment mark AM3 toward the fourth alignment mark AM4 may be parallel to the imaginary extension line extending from the first alignment mark AM1 toward the second alignment mark AM2 in the second direction DR2. The imaginary line connecting the first alignment mark AM1 and the second alignment mark AM2 and the imaginary line connecting the third alignment mark AM3 and the fourth alignment mark AM4 may be spaced apart from each other in the second direction DR2, however, the present disclosure is not so limited. According to an aspect, the imaginary line connecting the first alignment mark AM1 and the second alignment mark AM2 and the imaginary line connecting the third alignment mark AM3 and the fourth alignment mark AM4 may be positioned on the same line, but may have different distances from the imaginary line CL of the input sensor layer ISL.

The first alignment mark AM1 and the second alignment mark AM2 may have the same size and shape as each other, and the third alignment mark AM3 and the fourth alignment mark AM4 have the same size and shape as each other.

An alignment mark, which is adjacent to the pad area NDA-PD, such as the first alignment mark AM1 and the second alignment mark AM2, may be used as a visibility mark to check whether an attachment position of a flexible printed circuit board FPCB on the display panel DP is properly aligned prior to attachment of the flexible printed circuit board FPCB.

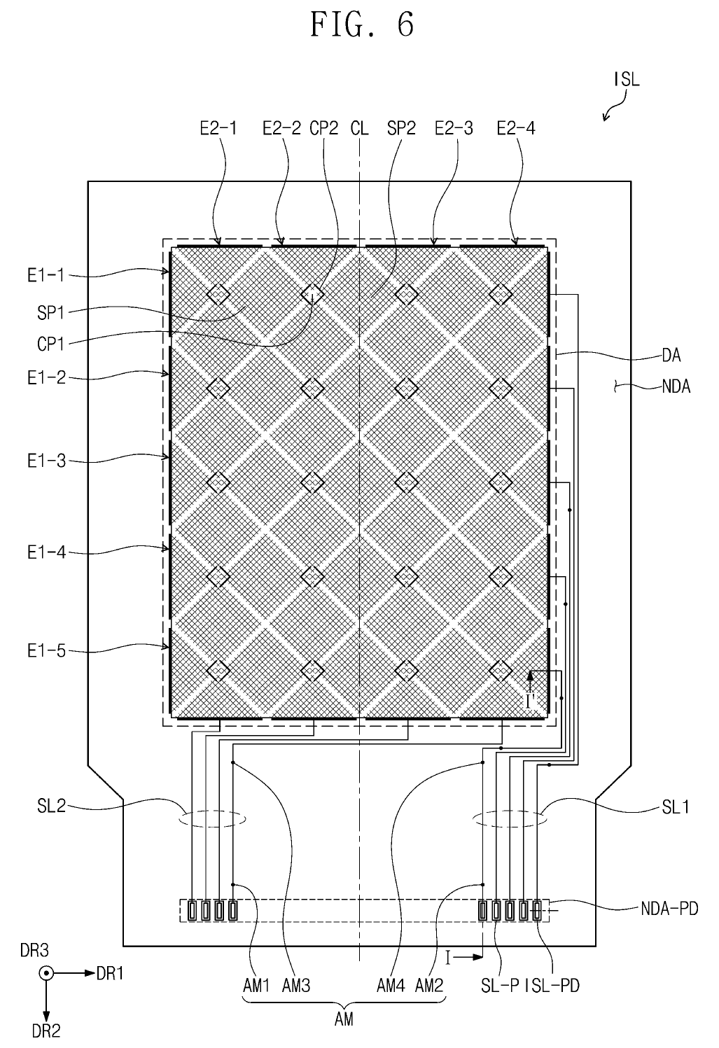

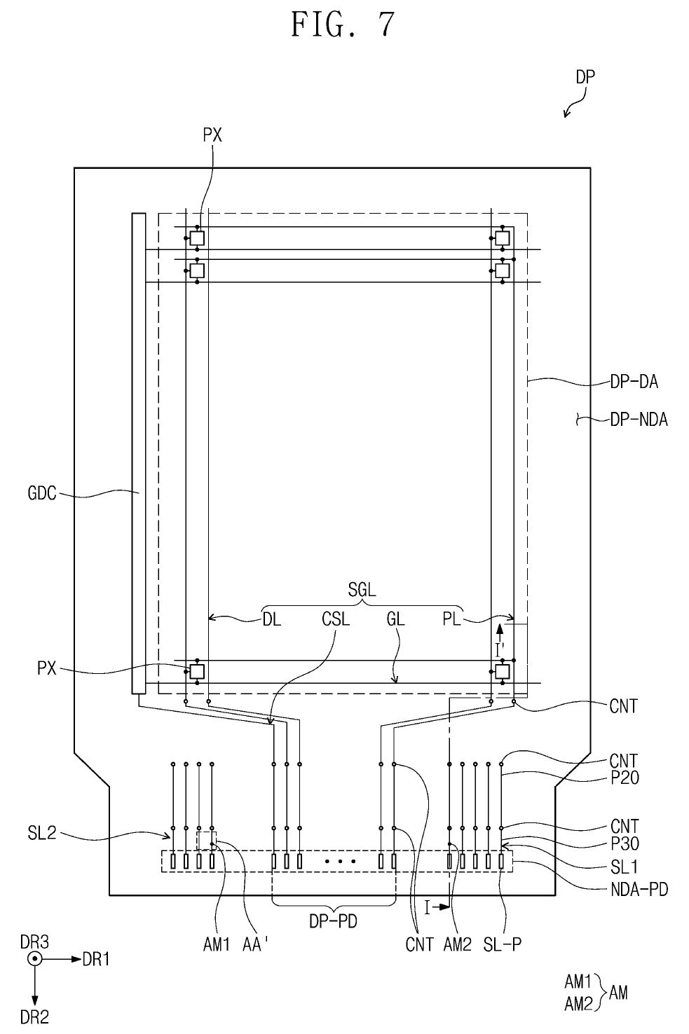

FIGS. 7 and 8 are plan views of the signal lines of the input sensor layer according to an aspect of the present disclosure.

FIGS. 7 and 8 show the signal lines including a plurality of portions disposed at different layers as a representative example. The signal lines SGL of the display panel DP and the input signal lines SL1 and SL2 of the input sensor layer ISL may include the plural portions.

The display panel of FIG. 7 may include the display area DP-DA and the non-display area DP-NDA, and the input sensor layer ISL of FIG. 8 may include a sensing area IS-DA and a non-sensing area IS-NDA adjacent to the sensing area IS-DA. The display area DP-DA and the non-display area DP-NDA of FIG. 7 may correspond to the display area DA and the non-display area NDA of FIG. 6, respectively, and the sensing area IS-DA and the non-sensing area IS-NDA of FIG. 8 may correspond to the display area DA and the non-display area NDA of FIG. 6, respectively.

Referring to FIGS. 7 and 8, the display panel DP may include the signal lines SGL and a portion of the input signal lines SL1 and SL2. Portions of the signal line SGL may be disposed at different layers, and the other portions may be disposed at the same layer. Portions of the input signal lines SL1 and SL2 may be disposed at different layers. A first portion P10 of the first input signal lines SL1 and the second input signal lines SL2 may be disposed on the input sensor layer ISL. A second portion P20 and a third portion P30 of the input signal lines SL1 and SL2 may be disposed on the display panel DP and may be adjacent to the signal pads to connect the input sensor electrode to the pads.

Referring to FIG. 7, the first alignment mark AM1 and the second alignment mark AM2 may be disposed in the third portion P30 of the input signal lines SL1 and SL2. Referring to FIG. 8, the third alignment mark AM3 and the fourth alignment mark AM4 may be disposed in the first portion P10 of the input signal lines SL1 and SL2. As described with reference to FIGS. 5 to 8, the alignment mark AM may be applied to all wiring structures including a metal component.

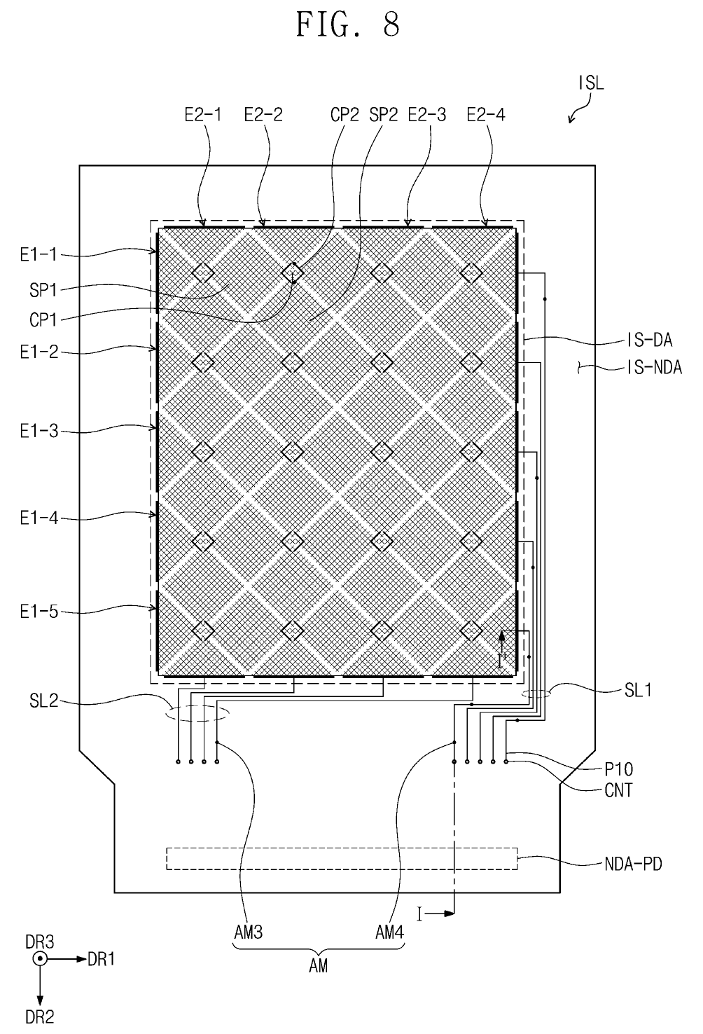

FIG. 9 is a cross-sectional view of the display device taken along a line I-I’ of FIG. 6.

The base layer BL, the circuit element layer DP-CL, the display element layer DP-OLED, the upper insulating layer TFL, and the input sensor layer ISL may be sequentially arranged in the display area DP-DA of the display device DD along the third direction DR3.

The circuit element layer DP-CL may be disposed on the base layer BL and may include at least one insulating layer and a circuit element. The circuit element may include a signal line, a pixel driving circuit, and the like. The circuit element layer DP-CL may be formed through a process of forming an insulating layer, a semiconductor layer, and a conductive layer using coating and deposition processes and a patterning process of the insulating layer, the semiconductor layer, and the conductive layer using a photolithography process.

A buffer layer BFL may include a plurality of inorganic layers stacked one on another. A semiconductor pattern may be disposed on the buffer layer BFL. The buffer layer BFL may increase an adhesion between the base layer BL and the semiconductor pattern.

A first insulating layer 10 may be disposed on the buffer layer BFL. The first insulating layer 10 may commonly overlap the pixels PX (refer to FIG. 6) and may cover the semiconductor pattern. The first insulating layer 10 may be an inorganic layer and/or an organic layer and may have a single-layer or multi-layer structure. The first insulating layer 10 may include at least one of aluminum oxide, titanium oxide, silicon oxide, silicon oxynitride, zirconium oxide, and hafnium oxide. Not only the first insulating layer 10, but also an insulating layer of the circuit element layer DP-CL, which will be described later, may be an inorganic layer and/or an organic layer and may have a single-layer or multi-layer structure.

In the display area DP-DA and IS-DA, a gate G1 may be disposed on the first insulating layer 10. The gate G1 may include multiple metal layers. The gate G1 may overlap a first region A1. The gate G1 may be used as a mask in a process of doping the semiconductor pattern.

A second insulating layer 20 may be disposed on the first insulating layer 10 and may cover the gate G1. The second insulating layer 20 may commonly overlap the pixels PX (refer to FIG. 6). An upper electrode UE may be disposed on the second insulating layer 20. The upper electrode UE may overlap the gate G1. The upper electrode UE may include multiple metal layers. According to an aspect, the upper electrode UE may be omitted. The semiconductor pattern may include the first region A1 having a relatively low doping concentration and conductivity and second regions S1 and D1 having a relatively high doping concentration and conductivity. One second region S1 may be disposed at one side of the first region A1, and the other second region D1 may be disposed at the other side of the first region A1. The second regions S1 and D1 may be doped with an N-type dopant or a P-type dopant. A P-type transistor may include a doped region doped with the P-type dopant. The first region A1 may be a non-doped region or a region doped at a concentration lower than that of the second regions S1 and D1.

The second regions S1 and D1 may serve as electrodes or signal lines. One second region S1 may correspond to a source of a transistor TR, and one second region D1 may be a drain of a transistor TR. FIG. 4 shows a portion a connection signal line SGL formed from the semiconductor pattern. Although not shown separately, the connection signal line SCL may be connected to the drain of the transistor TR.

A third insulating layer 30 may be disposed on the second insulating layer 20 and may cover the upper electrode UE. A first connection electrode CNE1 may be disposed on the third insulating layer 30. The first connection electrode CNE1 may be connected to the connection signal line SCL via a contact hole defined through the first, second, and third insulating layers 10, 20, and 30.

A fourth insulating layer 40 may be disposed on the third insulating layer 30. A fifth insulating layer 50 may be disposed on the fourth insulating layer 40. The fifth insulating layer 50 may be an inorganic layer. A second connection electrode CNE2 may be disposed on the fifth insulating layer 50. The second connection electrode CNE2 may be connected to the first connection electrode CNE1 via a contact hole defined through the fourth insulating layer 40 and the fifth insulating layer 50.

A sixth insulating layer 60 may be disposed on the fifth insulating layer 50 and may cover the second connection electrode CNE2. The sixth insulating layer 60 may be an organic layer. The organic light emitting diode OLED may be disposed on the sixth insulating layer 60 as a display element.

A first electrode AE (or an anode) may be disposed on the sixth insulating layer 60. The first electrode AE may be connected to the second connection electrode CNE2 via a contact hole defined through the sixth insulating layer 60. An opening OP may be defined through a pixel definition layer PDL, and at least a portion of the first electrode AE may be exposed through the opening OP of the pixel definition layer PDL. The pixel definition layer PDL may be an organic layer.

As shown in figures, the display area DP-DA may include a light emitting area PXA. In an aspect, the light emitting area PXA may be defined to correspond to the portion of the first electrode AE, which is exposed through the opening of the pixel definition layer PDL.

A light emitting layer EML may be disposed on the first electrode AE. A second electrode CE may be disposed on the light emitting layer EML. The second electrode CE may have an integral shape and may be commonly disposed in the multiple pixels PX (refer to FIG. 6). The upper insulating layer TFL may be disposed on the second electrode CE.

The upper insulating layer TFL may include a plurality of thin layers. The upper insulating layer TFL may include a capping layer CPL and a thin film encapsulation layer TFE disposed on the capping layer CPL.

The capping layer CPL may be disposed on the second electrode CE and may be in contact with the second electrode CE. The capping layer CPL may include an organic material.

The thin film encapsulation layer TFE may include a first inorganic layer IOL1, an organic layer OL, and a second inorganic layer IOL2. The first inorganic layer IOL1 and the second inorganic layer IOL2 may protect the display element layer DP-OLED (refer to FIG. 4) from moisture and oxygen, and the organic layer OL may protect the display element layer DP-OLED (refer to FIG. 4) from a foreign substance, e.g., dust particles.

The third portion P30 of the first input signal lines SL1, a pad portion SL-P, and the pad electrode ISL-PD connected to the pad portion SL-P may be arranged in the non-display area NDA. The pad portion SL-P and the third portion P30 may be disposed at the same layer and may be provided integrally with each other.

The second portion P20 may be disposed on the fifth insulating layer 50. The second portion P20 may be disposed at the same layer as the second connection electrode CNE2. The first portion P10, the second portion P20, and the third portion P30 may be connected to each other through a contact hole CNT.

The insulating pattern ILP may comprise a first insulating pattern ILP-a corresponding the second align mark AM2 in FIG. 7 and a second insulating pattern ILP-b corresponding the fourth align mark AM4 in FIG. 8. The insulating pattern ILP may be composed of insulating material. The insulating pattern ILP may have a width that decreases in the first direction DR1 as it extends along the third direction DR3. A thickness of the insulating pattern ILP at a second point, which is closer to a center of the insulating pattern ILP than a first point, may be greater than a thickness measured at the first point. As shown in FIG. 9, the insulating pattern ILP may have a slant surface when viewed in a cross-section, however, the present disclosure should not be so limited. According to an aspect, the insulating pattern ILP may be defined to have a convex shape with a semicircular or arc-shaped cross-section.

The first insulating pattern ILP-a may be disposed on the second insulating layer 20 in the non-display area NDA. A portion of the third portion P30 of the signal line may overlap the first insulating pattern ILP-a. The third portion P30 may have a protruding shape that corresponds to the shape of the first insulating pattern ILP-a. The third portion P30, which protrudes upward while overlapping the first insulating pattern ILP-a, may be used as the second alignment mark AM2 of FIG. 6.

The second alignment mark AM2 may be a portion of the third portion P30. The second alignment mark AM2 may include a metal component. When the input signal line SL1 electrically connects the pad electrode ISL-PD and the sensing electrode, it may also imply that the second alignment mark AM2 is electrically connected to both the pad electrode ISL-PD and the sensing electrode.

The third insulating layer 30 and the fourth insulating layer 40 may overlap the second alignment mark AM2. The area of the third insulating layer 30 and the fourth insulating layer 40 overlapping the insulating pattern ILP and the second alignment mark AM2 may protrude in the third direction DR3 along the area of the third insulating layer 30 and the fourth insulating layer 40 non-overlapping the insulating pattern ILP and the second alignment mark AM2. The third insulating layer 30 and the fourth insulating layer 40 may be optically transparent. The alignment mark AM may be optically visible through the third insulating layer 30 and the fourth insulating layer 40.

The input sensor layer ISL may be disposed on the display panel DP. The input sensor layer ISL may include a first insulating layer IS-IL1 (hereinafter, referred to as a base insulating layer), an intermediate insulating layer IS-IL2, a third insulating layer IS-IL3 (hereinafter, referred to as a protective insulating layer), and a first electrode E1-5. In the present aspect, each of the base insulating layer IS-IL1 and the protective insulating layer IS-IL3 may include an inorganic layer or an organic layer. The intermediate insulating layer IS-IL2 may be an organic layer. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

The second insulating pattern ILP-b may be disposed on the intermediate insulating layer IS-IL2 in the non-display area NDA. A portion of the first portion P10 of the signal line may overlap the second insulating pattern ILP-b. The first portion P10 may have a shape protruded along the shape of the second insulating pattern ILP-b. The first portion P10 protruded upward while overlapping the second insulating pattern ILP-b may be used as the fourth alignment mark AM4 of FIG. 6.

The alignment marks described in the present disclosure are not required to be included in display devices (or electronic devices), alignment marks may be added or excluded depending on the display device.

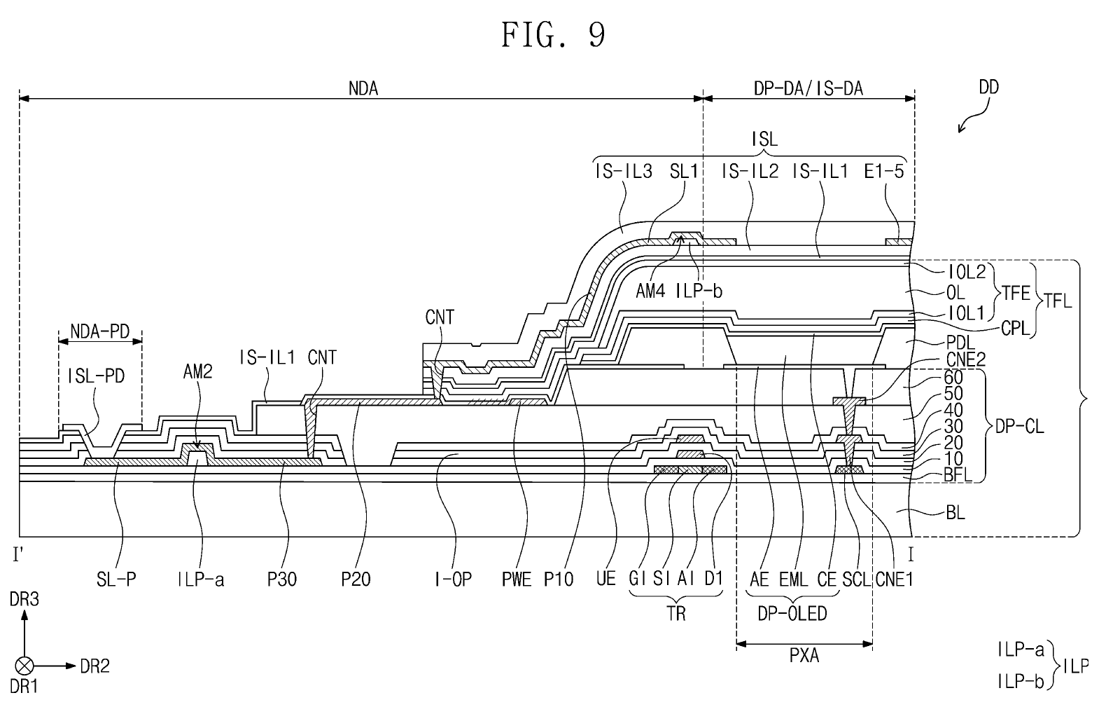

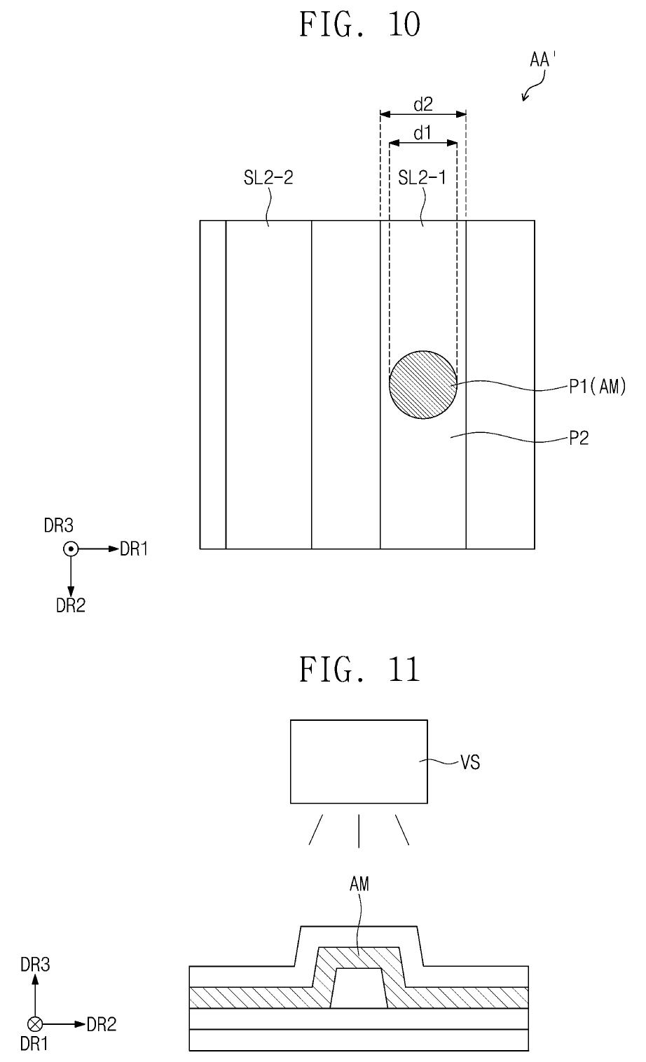

FIG. 10 is an enlarged plan view of a portion AA’ of FIG. 7. FIG. 11 is a schematic view of the imaging of an alignment mark.

Referring to FIG. 10, a second-first input signal line SL2-1 may be an input signal line that includes the alignment mark AM1 (refer to FIG. 7), and a second-second input signal line SL2-2 may be an input signal line that does not include the alignment mark AM1. The second-first input signal line SL2-1 may include a first portion P1 that overlaps the first insulating pattern ILP-a (refer to FIG. 9) and a second portion P2 that does not overlap the insulating pattern. The first portion P1 may be used as the alignment mark AM1 when viewed in the third direction DR3.

A width d1 may indicate a width of the first insulating pattern ILP-a (refer to FIG. 9). The width d1 of the first insulating pattern ILP-a (refer to FIG. 9) may be smaller than a width d2 of the second-first input signal line SL2-1. The first insulating pattern ILP-a (refer to FIG. 9) may be fully covered by the first portion P1.

Since the signal line includes a metal component, the direction and intensity of light reflected from its protruding portion versus its flat portion may differ as an upper portion protrudes upward. A strong highlight effect may occur at the protruding portion. Due to the strong highlight effect, the first portion P1 of the signal line may become more visible than the second portion P2 of the signal line. Accordingly, even though the first portion P1 has the width d2 smaller than the second-first input signal line SL2-1, the first portion P1 may be recognized by a vision sensor due to its distinct visibility.

Even when the first portion P1 and the second portion P2 have an integral shape, a boundary between the first portion P1 and the second portion P2 may be visually recognized due to a difference in luminance when the signal line is illuminated from above the upper surface of the substrate. For example, the first portion P1 may exhibit luminance higher than that of the second portion P2. Although the first portion P1 is depicted as being darker in FIG. 10, the first portion P1 may be perceived as brighter than the second portion P2. Depending on the illumination of the space captured by the vision sensor, the area of the first portion P1 may appear brighter while the other areas may be in the shadow of the first portion P1 and appear darker. In this case, an area of the first portion P1 appears brighter and the second portion P2 appears darker than the first portion P1, and thus, the first portion P1 may be clearly distinguished from the second portion P2.

Although not shown in figures, different alignment marks may be distinguished from each other by varying their sizes. The vision sensor may distinguish between different alignment marks based on the sizes of their recognized first portion P1.

Referring to FIG. 11, the vision sensor VS may recognize the alignment mark AM of the display device. The vision sensor VS may obtain location coordinates of the alignment mark AM. One alignment mark AM is shown in FIG. 11, however, the vision sensor VS may obtain coordinates of other alignment marks AM, for example the alignment mark that is symmetrically positioned. A processor within the vision sensor VS or a separate processor (not shown) that communicates electrically with the vision sensor VS may compare an alignment reference position of a coordinate system with the position of the alignment mark AM.

Although the aspects of the present disclosure have been described, it is understood that the present disclosure should not be limited to these aspects but various changes and modifications can be made by one ordinary skilled in the art within the spirit and scope of the present disclosure. Therefore, the disclosed subject matter should not be limited to any single aspect described herein.

What is claimed is:

1. A display device comprising:
a substrate comprising a display area and a non-display area outside the display area;
a pixel disposed in the display area;
an insulating pattern disposed in the non-display area; and
a signal line disposed on the substrate, the signal line comprising:
a first portion that overlaps the insulating pattern; and
a second portion that does not overlap the insulating pattern, wherein the first portion protrudes further from an upper surface of the substrate than the second portion, and the first portion of the signal line is an alignment mark.

2. The display device of claim 1, wherein the insulating pattern has a center point, a first point, and a second point closer to the center point than the first point; and wherein a second thickness of the insulating pattern at a second point is greater than a first thickness of the insulating pattern at the first point.

3. The display device of claim 1, wherein a luminance of the first portion is different from a luminance of the second portion when illuminated from above.

4. The display device of claim 2, wherein the insulating pattern has a width smaller than a width of the signal line.

5. The display device of claim 1, further comprising a second signal line spaced apart from the signal line in a first direction, the second signal line comprising a first portion, the first portion of the second signal line is a second alignment mark, and the first alignment mark and the second alignment mark are spaced apart from each other in the first direction.

6. The display device of claim 5, wherein the first signal line is disposed at one side of an imaginary center line of the substrate in the first direction, the second signal line is disposed at the other side of the center line, and the first alignment mark and the second alignment mark are symmetrical with each other with respect to the center line.

7. The display device of claim 1, further comprising an insulating layer disposed on the signal line, wherein an area of the insulating layer overlapping the insulating pattern protrudes further from the upper surface of the substrate than an area of the insulating layer not overlapping the insulating pattern.

8. The display device of claim 7, wherein the first portion of the signal line is visually recognizable above the insulating layer.

9. The display device of claim 1, further comprising a pad disposed in the non-display area, wherein the signal line electrically connects the pad and the pixel.

10. The display device of claim 1, further comprising:
a base insulating layer disposed on the pixel; and
an input sensor electrode disposed on the base insulating layer, wherein the signal line is electrically connected to the input sensor electrode.

11. The display device of claim 10, wherein the insulating pattern is disposed on the base insulating layer.

12. A display device comprising:
a substrate comprising a display area and a non-display area outside the display area;
a pixel disposed in the display area;
a pad disposed in the non-display area;
a signal line electrically connecting the pixel and the pad; and
an alignment mark defined by a protruding portion of the signal line, the protruding portion located in the non-display area.

13. The display device of claim 12, wherein a luminance of the alignment mark when illuminated from above is different from a luminance when illuminated from above of a portion of the signal line not a part of the alignment mark.

14. The display device of claim 12, further comprising a second signal line spaced apart from the signal line in a first direction, the signal line comprises the alignment mark, the second signal line comprises a second alignment mark, the first alignment mark and the second alignment mark are symmetrical with each other with respect to an imaginary center line of the substrate.

15. An electronic device comprising:
a display device; and
at least one processor controlling the display device, the display device comprising:
a substrate comprising a display area and a non-display area outside the display area;
a pixel disposed in the display area;
a pad disposed in the non-display area and electrically connected to the pixel;
a first insulating pattern disposed in the non-display area; and
a signal line electrically connected to the pad, the signal line comprising a first portion overlapping the first insulating pattern, the first portion protrudes further from an upper surface of the substrate than a second portion of the signal line, the second portion not overlapping the first insulating pattern, and a width of the first portion decreases as a distance from an upper surface of the substrate increases.

16. The electronic device of claim 15, wherein the first insulating pattern is fully covered by the signal line.

17. The electronic device of claim 15, further comprising a second signal line spaced apart from the signal line in a first direction, the first portion of the signal line is a first alignment mark, the second signal line comprising a first portion, the first portion of the second signal line is a second alignment mark, and the first alignment mark and the second alignment mark are spaced apart from each other in the first direction.

18. The electronic device of claim 17, wherein the first alignment mark and the second alignment mark are spaced apart from an edge of the display device by a same distance in a second direction perpendicular to the first direction.

19. The electronic device of claim 15, further comprising:
a circuit element layer disposed on the substrate, the circuit element layer comprising a transistor;
a display element layer disposed on the circuit element layer, the display element layer comprising a display element;
a thin film encapsulation layer disposed on the display element layer; and
an input sensor layer comprising an input sensor electrode disposed on the thin film encapsulation layer.

20. The electronic device of claim 19, further comprising:
a second insulating pattern disposed on the thin film encapsulation layer; and
an input signal line electrically connecting the pad and the input sensor electrode, the input signal line comprises a portion which overlaps the second insulating pattern in the non-display area, and the overlapping portion protrudes from the input signal line.
